(19) United States
(12) Patent Application Publication
(10) Pub. No.: US 2013/0229185 A1
(43) Pub. Date: Sep. 5, 2013

(54) TRAILER LIGHT TESTER

(71) Applicants: Alberto Filio, Laredo, TX (US); Manuel Rentena, Laredo, TX (US)

(72) Inventors: Alberto Filio, Laredo, TX (US); Manuel Rentena, Laredo, TX (US)

(21) Appl. No.: 13/412,084

(22) Filed: Mar. 5, 2012

(51) Int. Cl. G01R 31/44

(52) U.S. Cl. 324/414

(57) ABSTRACT

The present invention is a trailer light tester that includes a 7-way plug that is inserted into and connected to a trailer to check a plurality of various trailer lights of the trailer, an elongated casing and a turning and stop light switch that is disposed on the elongated casing. The trailer light tester also includes a taillight and marker light switch that is disposed on the elongated casing, a rechargeable battery that powers the elongated casing and a plurality of circuit breakers that are housed in the interior of the elongated casing and protect the trailer light tester against a short or damage from an excessive amount of current.

### TECHNICAL FIELD & BACKGROUND

Conventional methods of analysis involve heavy equipment requiring access to a commercial truck battery and a dolly for transporting the commercial truck battery. Currently there are limited alternatives to proficient and lightweight products capable of relatively easily transporting and testing a commercial truck battery.

The present invention generally relates to a testing device. More specifically, the invention is a trailer light tester.

It is an object of the invention to provide a trailer light tester that provides an individual with a time-efficient way of examining a commercial truck battery such as a recreational vehicle or RV.

It is an object of the invention to provide a trailer light tester that is relatively more portable, lighter in weight and easier to utilize than other traditional commercial truck battery testing devices and methods.

It is an object of the invention to provide a trailer light tester that can be utilized to test a commercial truck battery in a wet environment.

What is really needed is a trailer light tester that provides an individual with a time-efficient way of examining a commercial truck battery such as a recreational vehicle or RV that is relatively more portable, lighter in weight and easier to utilize than other traditional commercial truck battery testing devices and methods that can be utilized to test a commercial truck battery in a wet environment.

### BRIEF DESCRIPTION OF THE DRAWINGS

The present invention will be described by way of exemplary embodiments, but not limitations, illustrated in the accompanying drawings in which like references denote similar elements, and in which:

FIG. 1A illustrates a front view of a 7-way plug that is utilized in combination with a trailer light tester, according to an embodiment of the present invention.

FIG. 1B illustrates a side view of a trailer light tester, according to an embodiment of the present invention.

### DETAILED DESCRIPTION OF ILLUSTRATIVE EMBODIMENTS

Various aspects of the illustrative embodiments will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative embodiments. However, it will be apparent to one skilled in the art that the present invention may be practiced without the specific details. In other instances, well-known features are omitted or simplified in order not to obscure the illustrative embodiments.

Various operations will be described as multiple discrete operations, in turn, in a manner that is most helpful in understanding the present invention. However, the order of description should not be construed as to imply that these operations are necessarily order dependent. In particular, these operations need not be performed in the order of presentation.

The phrase “in one embodiment” is utilized repeatedly. The phrase generally does not refer to the same embodiment, however, it may. The terms “comprising”, “having” and “including” are synonymous, unless the context dictates otherwise.

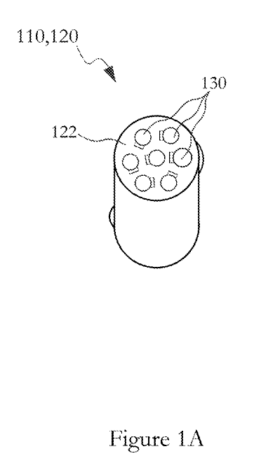

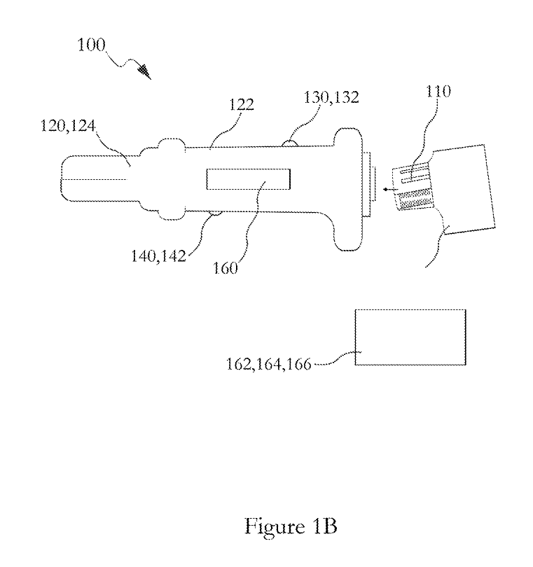

FIG. 1A illustrates a front view of a 7-way plug 110 of a trailer light tester 100, according to an embodiment of the present invention. The 7-way plug 110 is inserted into and connected to any suitable trailer to check if various trailer lights of the trailer are working. The 7-way plug 110 can be any other suitable plug that can be utilized with the trailer light tester 100.

The 7-way plug 110 includes a generally cylindrical body 120 and a plurality of outlet apertures 130. The generally cylindrical body 120 has a top portion 122 and is made of plastic although the generally cylindrical body 120 can be made of other suitable materials and have other suitable shapes as well. The outlet apertures 130 are disposed on the top portion 122 of the generally cylindrical body 120 and are inserted into the trailer to test if various trailer lights of a trailer are working. Additional details regarding the various trailer lights of a trailer that are tested by the trailer light tester 100 are illustrated and described in FIG. 1B and its description.

FIG. 1B illustrates a side view of a trailer light tester 100, according to an embodiment of the present invention.

The trailer light tester 100 includes a similar previously described 7-way plug 110 that was illustrated in FIG. 1A and its description, an elongated casing 120, a turning and stop light switch 130, a taillight and marker light switch 140, a battery 150 and a plurality of circuit breakers 160. The elongated casing 120 has an exterior surface 122 and an interior 124 and houses a plurality of components of the trailer light tester 100. The elongated casing 120 is approximately 11 inches long and weighs approximately 32 ounces and is made of plastic although the casing 120 can be other suitable lengths, weights and be made of other suitable materials as well. The turning and stop light switch 130 is disposed on the exterior surface 122 of the elongated casing 120 and activates and terminates a trailer's one or more turning lights and one or more stop lights to be tested. The turning and stop light switch 130 is a micro-switch mechanism 132 but can be any suitable switch mechanism. The taillight and marker light switch 140 is disposed on the exterior surface 122 of the elongated casing 120 and activates and terminates a trailer's one or more tail lights and marker lights to be tested. The turning and stop light switch 140 is a micro-switch mechanism 142 but can be any suitable switch mechanism. The battery 150 is typically a 14.4 V battery 152 that is also rechargeable and can accommodate and charge a 12V or a 14V light. The circuit breakers 160 are housed in the interior 124 of the elongated casing 120 and protect the trailer light tester 100 against a short or damage from an excessive amount of current. The circuit breakers 160 can also be utilized in combination with a wireless device 162 that can operate the circuit breakers 160. The wireless device 162 can be any suitable wireless device such as a Wi-Fi controlling device 164, a Bluetooth controlling device 166 or other suitable controlling device.

The trailer light tester is comprised of plastic and incorporates a 7-way plug, a switch for activating and terminating turning and stops lights and a switch for activating and terminating taillights and marker lights and is approximately 11 inches long and weighs approximately 32 ounces. The trailer light tester has a relatively compact design that affords users the convenience of a rechargeable 14.4 volt battery and features a plurality of circuit breakers that can be operated to prevent shortages. The trailer light tester connects to a trailer and is activated by a pair of relatively simple micro switch mechanisms. The trailer light tester may be readily available at retail hardware stores in various colors and styles. The trailer light tester is also water-tight, allowing use in a wide variety of conditions and environments, including rain and wet conditions and environments. The trailer light tester features a relatively compact design with an ability to fit into a standard tool box, allowing for maximum transportability and convenience.

While the present invention has been related in terms of the foregoing embodiments, those skilled in the art will recognize that the invention is not limited to the embodiments described. The present invention can be practiced with modification and alteration within the spirit and scope of the appended claims. Thus, the description is to be regarded as illustrative instead of restrictive on the present invention.

1. A trailer light tester, comprising:
a 7-way plug that includes a generally cylindrical body with a top portion and a plurality of outlet apertures that is inserted into and connected to a trailer to check a plurality of various trailer lights of said trailer;
an elongated casing with an exterior surface and an interior and houses a plurality of components of said trailer light tester;
a turning and stop light switch that is disposed on said exterior surface of said elongated casing and activates and terminates said trailer's one or more turning lights and one or more stop lights to be tested;
a taillight and marker light switch that is disposed on said exterior surface of said elongated casing and activates and terminates said trailer's one or more tail lights and marker lights to be tested;
a rechargeable battery that powers said elongated casing; and
a plurality of circuit breakers that are housed in said interior of said elongated casing and protect said trailer light tester against a short or damage from an excessive amount of current.

2. The tester according to claim 1, wherein said various trailer lights are selected from the group consisting of one or more turning lights, one or more stopping lights, one or more turning lights, one or more taillights and one or more marker lights.

3. The tester according to claim 1, wherein said outlet apertures are disposed on said top portion of said generally cylindrical body.

4. The tester according to claim 1, wherein said turning and stop light switch is a micro-switch mechanism.

5. The tester according to claim 1, wherein said taillight and marker light switch is a micro-switch mechanism.

6. The tester according to claim 1, wherein said rechargeable battery is an approximate 14.4 Volt battery.

7. The tester according to claim 1, wherein said rechargeable battery charges an approximate 12 Volt light or an approximate 14 Volt light.

8. The tester according to claim 1, wherein said circuit breakers are utilized in combination with a wireless device that operates said circuit breakers.

9. The tester according to claim 8, wherein said wireless device is a Wi-Fi controlling device.

10. The tester according to claim 8, wherein said wireless device is a Bluetooth controlling device.

11. A trailer light tester, comprising:
a 7-way plug that includes a generally cylindrical body with a top portion and a plurality of outlet apertures disposed on said top portion of said generally cylindrical body that is inserted into and connected to a trailer to check a plurality of various trailer lights of said trailer, wherein said various trailer lights are selected from the group consisting of one or more turning lights, one or more stopping lights, one or more turning lights, one or more taillights and one or more marker lights;
an elongated casing with an exterior surface and an interior and houses a plurality of components of said trailer light tester;
a turning and stop light micro-switch mechanism that is disposed on said exterior surface of said elongated casing and activates and terminates said trailer's one or more turning lights and one or more stop lights to be tested;
a taillight and marker light micro-switch mechanism that is disposed on said exterior surface of said elongated casing and activates and terminates said trailer's one or more tail lights and marker lights to be tested;
a rechargeable battery that powers said elongated casing; and
a plurality of circuit breakers that are housed in said interior of said elongated casing and protect said trailer light tester against a short or damage from an excessive amount of current.

12. The tester according to claim 11, wherein said generally cylindrical body is made of plastic.

13. The tester according to claim 11, wherein said elongated casing is made of plastic.

14. The tester according to claim 11, wherein said elongated casing is approximately 11 inches long.

15. The tester according to claim 11, wherein said elongated casing weighs approximately 32 ounces.

16. The tester according to claim 11, wherein said rechargeable battery is an approximate 14.4 Volt battery.

17. The tester according to claim 11, wherein said rechargeable battery charges an approximate 12 Volt light or an approximate 14 Volt light.

18. The tester according to claim 11, wherein said circuit breakers are utilized in combination with a wireless device that operates said circuit breakers.

19. The tester according to claim 18, wherein said wireless device is a Wi-Fi controlling device.

20. The tester according to claim 18, wherein said wireless device is a Bluetooth controlling device.
